(19) United States
(12) Patent Application Publication
(10) Pub. No.: US 2026/0077291 A1
(43) Pub. Date: Mar. 19, 2026

(54) METHOD AND DEVICE FOR REMOVING REACTIVE PARTICLES FROM A VACUUM ENVIRONMENT, AND PROCESS PLANT FOR PRODUCING MONOCRYSTALLINE SILICON INGOTS

(71) Applicant: Flowserve Management Company, Irving, TX (US)

(72) Inventors: Rayk Hencke, Itzehoe (DE); Stefan Lähn, Itzehoe (DE); Julian Drechsel, Itzehoe (DE); Nils Meggers, Itzehoe (DE); Jochen Schreiner, Itzehoe (DE)

(21) Appl. No.: 19/110,933

(22) PCT Filed: Sep. 13, 2023
(86) PCT No.: PCT/EP2023/075184

§ 371 Date: Mar. 12, 2025

(30) Foreign Application Priority Data
Sep. 15, 2022 (EP) 22195869.7

(51) Int. Cl. B01D 46/71; B01D 46/58; C30B 15/00; C30B 29/06

(52) U.S. Cl. CPC B01D 46/71; B01D 46/58; C30B 15/00; C30B 29/06; B01D 2273/28; B01D 2273/30

(57) ABSTRACT

The invention relates to a method for removing reactive particles from a vacuum environment (14), in which a process gas is conveyed from the vacuum environment (14) by means of a vacuum pump (21, 22). The process gas is passed between the vacuum environment (14) and the vacuum pump (21, 22) through a first filter (31) and a second filter (32) to filter reactive particles from the process gas. A liquid ring pump (35) is used to discharge particles from the first filter (31) and the second filter (32). In a first phase of the method, the first filter (31) is active and the second filter (32) is passive; in a second phase of the method, the first filter (31) is passive and the second filter (32) is active. In the first phase, the process gas is passed through the first filter (31) and the liquid ring pump (35) discharges particles from the second filter (32). In the second phase, the process gas is passed through the second filter (32) and the liquid ring pump (35) discharges particles from the first filter (31). The invention also relates to a device for removing reactive particles from a vacuum environment and to a process system for producing monocrystalline silicon ingots.

### BACKGROUND

The invention relates to a method and an apparatus for removing reactive particles from a vacuum environment. The invention also relates to a process plant for producing monocrystalline silicon ingots.

There is commonly a need to remove reactive particles from a vacuum environment in the case of process plants from which process gases are discharged. One example is the production of monocrystalline silicon ingots, which are formed from a silicon melt. The silicon melt is disposed in a vacuum housing into which argon is introduced as purge gas. While the silicon ingot is being formed, there is a continuous flow of the process gas through the continuous introduction of argon into the housing and suctioning thereof from the vacuum housing by means of a vacuum pump.

In the vacuum housing, the process gas comes into contact with the silicon ingot and the silicon melt and with other surfaces and thereby carries reactive particles along as it issues from the vacuum housing.

It is hitherto customary to accumulate the reactive particles in a filter disposed between the vacuum housing and the vacuum pump until silicon ingot formation has been completed. A phase in which the silicon ingot is removed from the vacuum housing or in which the silicon melt is replenished can be used for cleaning the filter and for removing the reactive particles.

If an excessively large amount of reactive particles accumulates in a filter, then problems may occur when the filters are cleaned. For example, dust balls which cannot be removed by simple blowing may form. Furthermore, contact between the reactive particles and oxygen may trigger chemical reactions in which heat energy is released. In the case of a large amount of reactive particles, the amount of heat released may be so great that damage to the filter occurs.

### SUMMARY

It is an object of the invention to provide a method and an apparatus for removing reactive particles from a vacuum environment and also an associated process plant that avoid these disadvantages. The object is achieved by the features of the independent claims. Advantageous embodiments are specified in the dependent claims.

The invention provides a method for removing reactive particles from a vacuum environment, the method comprising conveying a process gas from the vacuum environment by means of a vacuum pump and conducting the process gas between the vacuum environment and the vacuum pump through a first filter and a second filter in order to filter reactive particles out of the process gas. By means of a liquid-ring pump, particles are abstracted from the first filter and the second filter. In a first phase of the method, the first filter is active and the second filter is passive. In a second phase of the method, the first filter is passive and the second filter is active. In the first phase, process gas is conducted through the first filter and the liquid-ring pump abstracts particles from the second filter. In the second phase, process gas is conducted through the second filter and the liquid-ring pump abstracts particles from the first filter.

The alternating use of two parallel-connected filters between the vacuum environment and the vacuum pump makes it possible to schedule the cleaning of the filters independently of the processes in the vacuum housing. While one of the filters is in the active state and is filtering reactive particles out of the process gas conveyed by means of the vacuum pump, the other filter can be brought to a passive state in which it does not contribute to the processes in the vacuum housing. In the passive state, the reactive particles can be abstracted from the filter by means of the liquid-ring pump. An alternating operation in which, at any one time, one of the filters is active and the other is passive allows continuous conveying of process gas from the vacuum environment without excessive amounts of reactive particles accumulating in any of the filters.

The method is preferably carried out such that the process gas is continuously conveyed from the vacuum environment between the first phase and the second phase. Between the first phase of the method and the second phase of the method, there may be one or more transitional phases. The transitional phase may comprise a period in which parallel conduction of the process gas through both the first filter and the second filter occurs. It may be that the length of time required to abstract the particles from the passive filter is shorter than the length of time in which process gas is filtered by means of the active filter. In that case, the transitional phase may comprise periods in which the passive filter is completely inactive, i.e., it does not contribute to filtering the process gas and is not subjected to cleaning.

The first filter may be designed to filter the reactive particles out of the process gas by conducting the process gas through a filter material at which deposition of the reactive particles occurs. The filter material may be in particular a porous material. By means of the filter material, a primary filter space may be separated from a secondary filter space. The process gas coming from the vacuum environment may be introduced into the primary filter space and cross through the porous material into the secondary filter space. From the secondary filter space, the filtered process gas may be abstracted by means of the vacuum pump.

The porous material may form a tubular structure. The outside of the tubular structure may be adjacent to the primary filter space, and the inside of the tubular structure may be adjacent to the secondary filter space. The tubular structure may be vertical. A first end of the tubular structure may be closed, and a second end of the tubular structure may be open. The second end may communicate with the secondary filter space. The second end may be the top end of the tubular structure. The second filter may have the same features as the first filter.

While the process gas is being filtered by means of the active filter, a vacuum is applied in the active filter. After a switch has been made to the passive state, an oxygen-containing gas can be admitted into the passive filter in a first transitional phase, and the pressure in the passive filter therefore rises. In one embodiment, ambient air is admitted into the passive filter, thus bringing the passive filter to atmospheric pressure. Another possibility is to admit compressed air of a pressure higher than atmospheric pressure into the passive filter or to admit a gas having an oxygen content higher than that of air into the passive filter. For this purpose, the filter may comprise a ventilation valve which is opened for admittance of the gas and which is closed in the active state of the filter. The admittance of the gas may take place at the start of the passive state of a filter, i.e., before the particles are abstracted from the filter by means of the liquid-ring pump.

The admittance of the gas leads to chemical reactions, in particular between the reactive particles and oxygen, in which heat energy is released. The reactive particles at least partly lose their reactivity, thus reducing the risk of ignition or explosion.

The oxygen-containing gas which floods the interior of the passive filter may be admitted into the secondary filter space. This can produce a counterflow through the filter material that is opposite to the flow direction of the process gas in the active state of the filter. The counterflow may extend from the secondary filter space through the filter material into the primary filter space. The ventilation valve may be opened rapidly, such that there is a sudden flow into the interior of the passive filter. The counterflow detaches particles which have settled on the filter material. At the same time, the reactive particles may be reacted through the intense contact with the incoming gas, thereby reducing the reactivity of the particles. The particles detached from the porous material are initially distributed in the primary filter space before sinking to the bottom.

The liquid-ring pump may be connected to a lower portion of the first filter and/or the second filter, thus allowing particles accumulated there to be abstracted by means of the liquid-ring pump. The liquid-ring pump may be connected to the primary filter space of the first filter and/or the second filter. The bottom of the first and second filters may be in the form of a sloping surface, such that the particles are conducted to the port of the liquid-ring pump. The port of the liquid-ring pump may be disposed at the lower end of the sloping surface. While the particles are being abstracted from the passive filter, fresh air may be exchanged between the interior of the passive filter and the environment, thus avoiding the formation of a vacuum in the interior of the passive filter.

The abstracting of the particles from the passive filter may be made easier if the particles accumulated at the bottom of the passive filter are brought to a fluidized state. A fluidization device may be provided, by means of which a fluidizing gas flow is introduced into the accumulated particles.

The particles abstracted in the direction of the liquid-ring pump mix inside the liquid-ring pump with the operating liquid which forms the liquid ring. Chemical reactions between the particles and the operating liquid may contribute to further reducing the reactivity of the particles. The particles may be discharged from the liquid-ring pump together with the operating liquid of the liquid-ring pump. During operation of the liquid-ring pump, the operating liquid may be exchanged, such that operating liquid having a higher proportion of particles is discharged from the liquid-ring pump and operating liquid having a lower proportion of particles is supplied to the liquid-ring pump.

The operating liquid may be exchanged continuously during operation of the liquid-ring pump. The operating liquid may be water. Fresh water or treated water may be supplied to the liquid-ring pump. Another possibility is to accumulate the particles in the operating liquid up to a specified concentration and to exchange the operating liquid once the concentration is reached.

The feature “liquid-ring pump” in the context of the invention does not imply any restriction with respect to the number of units. The liquid-ring pump according to the invention may consist of two units, such that the first unit is connected to the first filter and the second unit is connected to a second filter. Preferably, the liquid-ring pump is in the form of a single unit which communicates alternatingly with the first filter and the second filter.

The gas conveyed by means of the liquid-ring pump may be collected or it may be discharged to the environment. The gas may contain reactive gaseous constituents such as hydrogen. In order to avoid hazards, the gas may be diluted after it has issued from the liquid-ring pump, for example by supplying air, until the concentration of combustible substances in the gas is below the lower explosive limit (LEL).

Following the removal of the particles, the passive filter may be prepared for transition to the active state in a second transitional phase. To this end, the connection between the interior of the passive filter and the liquid-ring pump may be closed. Likewise, the ventilation valve by means of which the interior of the passive filter communicates with the environment may be closed. In the interior of the passive filter may be applied a vacuum which corresponds to the vacuum in the interior of the active filter. Once the same pressure is applied in both filters, the hitherto passive filter can be connected into the process gas flow between the vacuum housing and the vacuum pump. Once this is done, the hitherto active filter may be separated from the process gas flow between the vacuum housing and the vacuum pump, and the hitherto active filter therefore transitions to the passive state.

The cleaning interval, i.e., the length of time for operation of a filter in the active state, may be ascertained according to the state of the active filter. One criterion may be, for example, that the pressure difference between the primary filter space and the secondary filter space has exceeded a specified threshold. A high pressure difference may be an indication that a specific amount of reactive particles has settled in the filter. Additionally or alternatively, the weight of the active filter may be used to infer a specific amount of reactive particles in the active filter and a switch may be made to the passive state when a specified threshold for the weight is exceeded. In a further variant, a switch is made from the active state to the passive state after a specified period of time has passed.

The evacuation of the passive filter before the transition to the active state may be carried out by means of the same vacuum pump that also generates the vacuum for the vacuum environment. This procedure may adversely affect process stability in the vacuum environment because pressure may fluctuate in the vacuum environment during the evacuation of the passive filter. In one embodiment, therefore, an auxiliary vacuum pump is provided, by means of which the passive filter is evacuated before the transition to the active state.

The auxiliary vacuum pump may have the additional function of evacuating a lock chamber via which articles are introduced into the vacuum environment or removed from the vacuum environment. Before the transfer of articles between the vacuum environment and the lock chamber, the lock chamber is evacuated to the same pressure applied in the vacuum environment. This is also the pressure to which the passive filter is brought before the transition to the active state, and so in both cases the same requirements apply to the auxiliary vacuum pump.

The process gas conveyed by means of the (main) vacuum pump may be supplied to a treatment station in which the process gas is treated such that it is suitable for reuse for the process in the vacuum environment. In particular, argon may be regenerated from the process gas in the treatment station and be provided for reuse. There may be a connecting line between the treatment station and the vacuum environment, such that the treated process gas is returned to the vacuum environment in the form of a closed circuit.

The feature “vacuum pump” in the context of the invention does not imply any restriction with respect to the number of units. The vacuum pump according to the invention may consist of two units, such that the first unit is connected to the first filter and the second unit is connected to the second filter. Preferably, the vacuum pump is in the form of a single unit which communicates alternatingly with the first filter and the second filter.

In one embodiment, the vacuum pump according to the invention is in the form of a sequence of two vacuum pump units connected one after the other. The inlet of the second vacuum pump unit may be connected to the outlet of the first vacuum pump unit, such that each of the vacuum pump units applies only part of the pressure difference between the vacuum pump and atmospheric pressure. This can improve the energy efficiency of the vacuum pump.

In order to avoid contamination of the process gas by an operating liquid or lubricants of the vacuum pump, the vacuum pump is preferably in the form of a dry-running vacuum pump. In a preferred embodiment, the vacuum pump is a screw pump. The same may apply to the auxiliary vacuum pump and/or the vacuum pump units.

The invention also relates to an apparatus for removing reactive particles from a vacuum environment, comprising a vacuum housing and comprising a vacuum pump connected to the vacuum housing. Disposed between the vacuum housing and the vacuum pump are a first filter and a second filter for filtering reactive particles out of a process gas conveyed by means of the vacuum pump. The apparatus comprises a liquid-ring pump for suctioning particles from the first filter and the second filter. By means of a switching device, the apparatus is brought to a first switching state and a second switching state, such that in the first switching state the process gas is conducted through the first filter and the liquid-ring pump abstracts particles from the second filter and such that in the second switching state the process gas is conducted through the second filter and the liquid-ring pump suctions particles from the first filter.

The invention further relates to a process plant comprising a vacuum housing and an apparatus according to the invention connected to the vacuum housing for removing reactive particles from the vacuum environment of the vacuum housing. The process plant may comprise a lock chamber for transferring articles into the vacuum housing and/or transferring articles out of the vacuum housing. The process plant may comprise an auxiliary vacuum pump designed to evacuate the lock chamber and designed to evacuate the passive filter before the transition to the active state. The process plant may comprise a closed process gas circuit which extends from the vacuum housing via the vacuum pump to a process gas treatment station and from the process gas treatment station back to the vacuum housing.

The process plant may be designed to produce monocrystalline silicon ingots. In the vacuum housing may be disposed a melting furnace by means of which a silicon melt is produced. The lock chamber may be designed for transferring a silicon seed into the vacuum housing and transferring the finished silicon ingot out of the vacuum housing. The invention also relates to a method for operating such a process plant.

The disclosure encompasses developments of the apparatus and the process plant that are described in the context of the method according to the invention. The disclosure encompasses developments of the method described in the context of the apparatus according to the invention or the process plant according to the invention.

### BRIEF DESCRIPTION OF THE DRAWINGS

The invention is described by way of example below on the basis of advantageous embodiments with reference to the accompanying drawings, in which:

FIG. 1: shows a first embodiment of a process plant according to the invention;

FIG. 2: shows an enlarged view of a filter from FIG. 1;

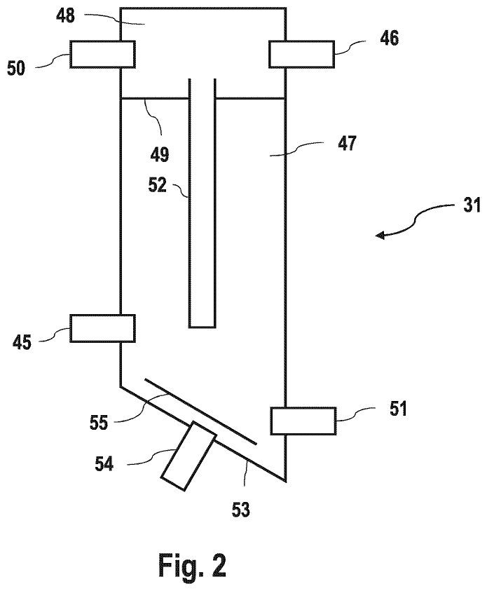

FIG. 3: shows a second embodiment of a process plant according to the invention.

### DETAILED DESCRIPTION

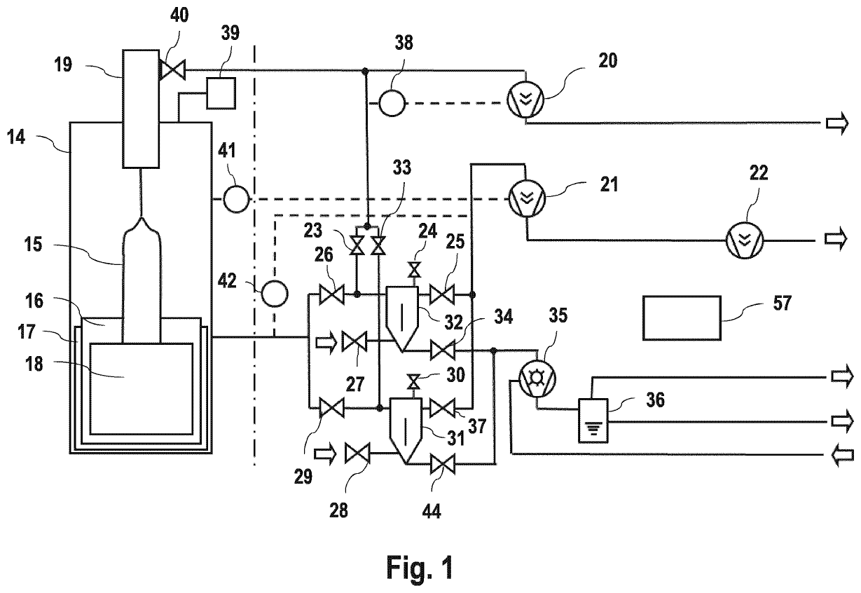

A process plant as shown in FIG. 1 comprises a vacuum housing 14 in which a vacuum is applied by means of a system composed of a first screw pump 21 and a second screw pump 22. The system composed of the screw pumps 21, 22 forms a vacuum pump in the context of the invention. From a first pressure sensor 41, the screw pump 21 receives information about the pressure in the vacuum housing 14, such that a specified pressure can be generated in the vacuum housing 14 in a controlled operation. Disposed in the vacuum housing 14 is a crucible 16 which is made of a ceramic material and is upwardly open. The crucible 16 is surrounded by a heating device 17, thus allowing provision of a silicon melt 18 in the crucible 16.

The process plant comprises a lock chamber 19 into which a silicon seed crystal is introduced at atmospheric pressure. After the lock chamber 19 is closed, a vacuum is generated in the lock chamber 19 by means of a third vacuum pump 20. The third vacuum pump 20, which forms an auxiliary vacuum pump in the context of the invention, receives information about the pressure in the lock chamber 19 from a second pressure sensor 38, such that a specified pressure can be generated in the lock chamber 19 in a controlled operation. Once the pressure in the lock chamber 19 is identical to the pressure in the vacuum housing 14, the lock chamber 19 is opened toward the vacuum housing 14. The seed crystal is lowered on a wire cable until the seed crystal comes into contact with the surface of the melt 18. As the wire cable is withdrawn slowly, silicon material from the melt 18 settles on the seed crystal, thus forming a silicon ingot 15. The finished silicon ingot is transferred into the lock chamber 19. The lock chamber 19 is separated from the vacuum housing 14, the valve 40 is closed and the lock chamber 19 is returned to atmospheric pressure, thus allowing removal of the silicon ingot 15.

From an argon supply 39, argon is continuously introduced into the vacuum housing 14 as process gas. The argon acts as a purge gas by means of which interfering particles and other constituents of the atmosphere are abstracted from the vacuum housing 14. Interfering particles are formed, for example in the form of silicon oxides, when the melt reacts with oxygen. The presence of oxygen in the vacuum atmosphere cannot be completely prevented, for example because of outgassing from components in the vacuum housing 14.

The melt may contain materials for doping the silicon ingot. In the case of N-doped single crystals, for example, a suitable doping material is red phosphorus. Highly reactive dusts can form from red phosphorus and they can interfere with the formation of the silicon ingot.

As a result of the flow of the argon purge gas that is maintained by the screw pumps 21, 22, the reactive particles are picked up and abstracted from the vacuum housing 14. The apparatus according to the invention depletes the enriched argon purge gas of the reactive particles before the argon purge gas reaches the first screw pump 21.

For this purpose, a first filter 31 and a second filter 32 are disposed between the vacuum housing 14 and the first screw pump 21. The filters 31, 32 are parallel to each other, meaning that the process gas can pass through either the first filter 31 or the second filter 32. This allows the possibility of bringing one of the two filters 31, 32 to a passive state in which it can be cleaned. A control unit 57 controls valves 23, 24, 25, 26, 27, 28, 29, 30, 33, 34, 44, such that each of them assumes the desired state. The control unit 57 forms a switching device in the context of the invention.

In a first phase of an operating cycle, the first filter 31 is active and the second filter 32 is passive. The valves 27, 37 are open, whereas the valves 28, 30, 44, 33 are closed, such that the process gas can flow from the vacuum chamber 14 through the first filter 31 to the first screw pump 21. The valves 25, 26 are closed, such that no process gas can flow through the second filter 32.

The first filter 31 has a stainless steel housing, and formed within said housing is a partition wall 49 which separates a primary filter space 47 from a secondary filter space 48. Formed in the primary filter space 47 is an inlet opening 45 which communicates with the vacuum housing 14. Formed in the secondary filter space 48 is an outlet opening 46 which communicates with the first screw pump 21. Between the primary filter space 47 and the secondary filter space 48, the process gas passes through a filter cartridge 52 consisting of a porous material. The reactive particles in the enriched process gas are deposited on the outside of the filter cartridge 52 and in the pores, such that the process gas entering the interior of the filter cartridge 52 is depleted of the reactive particles. The purified process gas issues from the first filter 31 via the secondary filter space 48 and is conducted to the first screw pump 21. Since the process gas is depleted of reactive constituents, it can be safely discharged to the environment at the outlet of the second screw pump 22. Over time, more and more particles settle on the filter cartridge 52, which means that the filter has to be cleaned at regular intervals to remove the particles from the filter.

The second filter 32 has the same structure as the first filter 31. Following a phase in the active state, the second filter 32 has been brought to the passive state in order to carry out cleaning. Following closure of the valves 25, 26, process gas no longer flows between the inlet opening 45 and the outlet opening 46. In a first step, the ventilation valve 24 is opened, such that air from the atmosphere enters the secondary filter space 48 through a supply air opening 50. Alternatively, a compressed air source or an oxygen supply may also be connected to the ventilation valve 24. The pressure difference between atmospheric pressure and the pressure in the interior of the second filter 32 produces a strong flow from the secondary filter space 48 into the primary filter space 47, which passes through the filter cartridge 52 in the form of a counterflow. Particles adhering to the filter cartridge 52 become detached and are initially distributed in the primary filter space 47 with the air flow before sinking to the bottom.

Contact with the oxygen in the air causes the particles to react, thereby releasing heat. The cleaning cycles are set such that the heat released is insufficient to cause damage to the second filter 32. A grate 55 is disposed parallel to the bottom of the second filter 32 that is in the form of a sloping surface 53. By means of a fluidization device connected to the valve 27, an air flow is introduced through a fluidization opening 54 into the second filter 32, which air flow is distributed between the sloping surface 53 and the grate 55 and passes through the grate from below. The air flow brings the particles collecting at the bottom of the second filter 32 to a fluidized state.

The fluidized particles are suctioned from the second filter 32 through a cleaning opening 51 by means of a liquid-ring pump 35. The phase in which the liquid-ring pump 35 is in operation to abstract particles from the second filter 32 is the first phase of an operating cycle in the context of the invention. A previous phase is referred to as the first transitional phase, and a phase following the first phase is referred to as the second transitional phase.

During operation, the liquid-ring pump 35 is continuously supplied with fresh water as operating liquid. A corresponding amount of operating liquid is discharged via the outlet of the liquid-ring pump 35 and conveyed to a collecting vessel 36. The particles abstracted from the second filter 32 mix with the operating liquid and reach the collecting vessel 36 together with the operating liquid. Particles which have not yet completely lost their reactivity by then can react further through contact with the operating liquid. Gaseous constituents are upwardly discharged from the collecting vessel 36. If reactive gaseous constituents are present, the discharged gas can be diluted with air before being released into the environment. The operating liquid enriched with the particles is likewise removed from the collecting vessel 36 and treated.

After the particles have been removed from the second filter 32, the valves 24, 27, 34 are closed again and the second filter 32 is prepared for the transition to the active state in a second transitional phase. To this end, the valve 23 is first opened, such that the interior of the second filter 32 is evacuated by the third vacuum pump 20. Once the pressure in the interior of the second filter 32 is identical to the pressure in the interior of the first filter 31, the second filter 32 is ready for the transition to the active state and the valve 23 is closed again.

A pressure sensor is used to monitor the pressure difference between the inlet opening 45 and the outlet opening 46 of the first filter 31. The greater the amount of particles accumulated in the first filter 31, the greater the pressure difference, meaning that a threshold for the pressure difference can be defined, cleaning of the first filter 31 being necessary when said threshold is reached. When the threshold is reached, the valves 25, 26 are opened, such that the second filter 32 transitions to the active state. The valves 29, 37 are closed to bring the first filter 31 to the passive state.

The cleaning of the first filter 31 begins, as described, with the opening of the valve 30, such that air from the environment enters the secondary filter space 48. Following activation of a fluidization device connected to the valve 28 and following opening of the valve 44, the first filter 31 is connected to the liquid-ring pump 35, such that the particles can be suctioned. Thereafter, the valves 28, 30, 44 are closed and the valve 33 is opened in order to evacuate the interior of the first filter 31, such that the first filter 31 is ready for another transition to the active state. The respective valves are actuated in a damped manner in order to minimize the effects on the pressure of the process gas. The exception are the ventilation valves 24, 30, which are opened rapidly in order to produce a very sudden flow into the interior of the filters 31, 32.

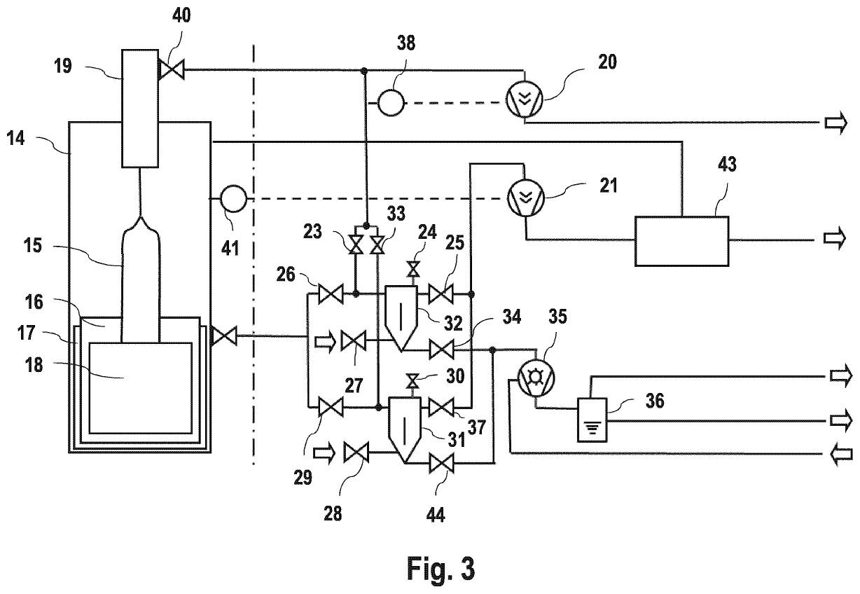

In the alternative embodiment according to FIG. 3, the vacuum pump which generates the vacuum in the vacuum housing 14 is a single screw pump 21. Connected to the outlet of the screw pump 21 is a treatment device 43 in which the process gas conveyed from the vacuum housing 14 and depleted of reactive particles is treated. The resultant pure argon from the treatment is returned to the vacuum housing 14, where it can act as a purge gas once more. Other constituents of the process gas are released to the environment.

The basis for ascertaining the cleaning intervals is not the differential pressure across the filters 31, 32, but length of time. When the process gas has passed through the active filter for a specified period of time, it is assumed that a sufficient amount of particles has accumulated, and cleaning is therefore due.

1. A method for removing reactive particles from a vacuum environment (14), the method comprising conveying a process gas from the vacuum environment (14) by means of a vacuum pump (21, 22), conducting the process gas between the vacuum environment (14) and the vacuum pump (21, 22) through a first filter (31) and a second filter (32) in order to filter reactive particles out of the process gas, and abstracting particles from the first filter (31) and the second filter (32) by means of a liquid-ring pump (35), wherein in a first phase of the method the first filter (31) is active and the second filter (32) is passive, wherein in a second phase of the method the first filter (31) is passive and the second filter (32) is active, wherein in the first phase the process gas is conducted through the first filter (31) and the liquid-ring pump (35) abstracts particles from the second filter (32), and wherein in the second phase the process gas is conducted through the second filter (32) and the liquid-ring pump (35) abstracts particles from the first filter (31).

2. The method of claim 1, wherein process gas is continuously conveyed from the vacuum environment (14) between the first phase and the second phase.

3. The method of claim 1, wherein the first filter (31) and/or the second filter (32) comprise a primary filter space (47) and a secondary filter space (48) which are separated from one another by a filter material (52), and wherein the process gas crosses from the primary filter space (47) through the filter material (52) into the secondary filter space (48).

4. The method of claim 1, wherein in a first transitional phase an oxygen-containing gas is admitted into the passive filter (31, 32).

5. The method of claim 4, wherein the oxygen-containing gas is admitted into the secondary filter space (48), such that a counterflow through the filter material (52) is produced.

6. The method of claim 4, wherein the liquid-ring pump (35) is connected to the primary filter space (47) of the first filter (31) and/or the second filter (32).

7. The method of claim 1, wherein the particles abstracted from the passive filter (31, 32) are discharged from the liquid-ring pump together with an operating liquid of the liquid-ring pump (35).

8. The method of claim 1, wherein the process gas issuing from the vacuum pump (21, 22) is treated for reuse in the vacuum environment (14).

9. The method of claim 8, wherein argon is regenerated from the process gas.

10. An apparatus for removing reactive particles from a vacuum environment, comprising a vacuum housing (14) and comprising a vacuum pump (21, 22) connected to the vacuum housing (14), there being disposed between the vacuum housing (14) and the vacuum pump (21, 22) a first filter (31) and a second filter (32) for filtering reactive particles out of a process gas conveyed by means of the vacuum pump (21, 22), comprising a liquid-ring pump (35) for suctioning particles from the first filter (31) and the second filter (32), and comprising a switching device (57) for bringing the apparatus to a first switching state and a second switching state, such that in the first switching state the process gas is conducted through the first filter (31) and the liquid-ring pump (35) abstracts particles from the second filter (32) and such that in the second switching state the process gas is conducted through the second filter (32) and the liquid-ring pump (35) suctions particles from the first filter (31).

11. A process plant comprising the apparatus of claim 10, wherein monocrystalline silicon ingots are produced in the vacuum housing (14) and wherein process gas released by the vacuum pump (21, 22) is treated and is returned to the vacuum housing (14).
